(19) United States
(12) Patent Application Publication
(10) Pub. No.: US 2010/0226411 A1
(43) Pub. Date: Sep. 9, 2010

(54) LOW-NOISE AMPLIFIER AND RADIO COMMUNICATION SYSTEM

(76) Inventors: Manabu Watanabe, Osaka (JP); Hiroshi Kimura, Hyogo (JP); Junji Nakatsuka, Osaka (JP)

Correspondence Address: MCDERMOTT WILL & EMERY LLP, 600 13TH STREET, NW, WASHINGTON, DC, 20005-3096, US

(21) Appl. No.: 12/159,572

(22) PCT Filed: Apr. 18, 2007
(86) PCT No.: PCT/JP2007/058451

§ 371 Date: Jun. 27, 2008

(30) Foreign Application Priority Data
Sep. 20, 2006 (JP) 2006-254228

(51) Int. Cl. H04L 27/00; H03F 3/16

(52) U.S. Cl. 375/130; 330/277

(57) ABSTRACT

Power consumption of an amplification circuit (11) for amplifying an inputted signal is switchable. A control circuit (12) switches the power consumption of the amplification circuit (11) such that data blank periods include an interval during which the power consumption of the amplification circuit (11) is smaller than during data periods.

### TECHNICAL FIELD

The present invention relates to a low-noise amplifier for amplifying an input signal, and a radio communication system using the low-noise amplifier.

### BACKGROUND ART

In recent years, with a rapid increase of information amount, greater capacity and higher speed have been needed for exchanging and transmitting information data. In order to meet such needs, the technologies relating to radio communication have been developed at a fast pace. Particularly, use of the radio communication has been spreading extensively, from offices to homes, for such reasons as no need of wiring by cables etc. More particularly, ultra wide-band communication (hereinafter referred to as UWB communication: UWB is an abbreviation for Ultra Wide Band) has been attracting more attention due to its expectable low power consumption.

In the UWB communication, an ultra wide-band signal using a band not less than 1.5 GHz or a band not less than 25% of a center frequency is adopted, and the impulse radio type (IR type) for communications based on an impulse signal is proposed. In the IR type, not a continuous signal used for typical communications but an intermittent impulse signal is employed for communication.

The UWB communication is applicable to, for example, sensor networks etc. Such applications need long-time operations with batteries or the like, and therefore the communication system used for the UWB communication needs reduction in power consumption.

In an example of the communication systems designed for reduction in power consumption, a power amplifier used for a transmitting circuit for mobile communication includes a series circuit of a resistance element and a switching element and a transistor connected to the series circuit wherein a circuit current value is switched by the switching element in accordance with a transmission output (for example, see Patent Document 1).

According to this communication system, power consumption of a transmitting circuit can be suppressed during reception of a signal.

Patent Document 1: Japanese Patent No. 3606366

### DISCLOSURE OF INVENTION

### Problems to be Solved by the Invention

However, in the above-described communication system, the ON/OFF state of the transistor of the amplifier in the transmitting circuit is controlled in accordance with the transmission output, and therefore, during the transmission, the power consumption remains at a conventional level and reduction in the power consumption cannot be expected. That is, in the above-described amplifier, it is impossible to control the power consumption during periods where a signal is inputted, and therefore reduction in the power consumption cannot be expected during the periods.

The present invention was conceived in view of the above-described problems and has an object of realizing reduction in power consumption in the process of amplifying an input signal in which data periods with information and data blank periods without information alternately occur, such as an impulse signal in IR communications, by controlling the power consumption even during periods where the signal is inputted.

### Means for Solving the Problems

In order to solve the above-described problems, an aspect of the present invention is a low-noise amplifier for amplifying an input signal in which data periods and data blank periods alternately occur, the input signal including information during the data periods but no information during the data blank periods, the low-noise amplifier having:

an amplification circuit for amplifying the input signal, power consumption of the amplification circuit being switchable; and

a control circuit switching the power consumption of the amplification circuit such that the data blank periods include an interval during which the power consumption of the amplification circuit is smaller than during the data periods.

### EFFECTS OF THE INVENTION

According to the present invention, in the process of amplifying an input signal in which data periods with information and data blank periods without information alternately occur, such as an impulse signal in IR communications, reduction in power consumption is possible since the power consumption can be controlled even during periods where the signal is inputted.

### BRIEF DESCRIPTION OF DRAWINGS

FIG. 1 is a block diagram illustrating an arrangement of a low-noise amplifier 10 according to Embodiment 1.

FIG. 2 illustrates timing charts of the RF input signal RFIN, a control signal, and the output signal RFOUT.

FIG. 3 is a block diagram illustrating an arrangement of a low-noise amplifier 20 according to Embodiment 2.

FIG. 4 is a block diagram illustrating an arrangement of the low-noise amplifier according to a variation of Embodiment 2.

FIG. 5 is a block diagram illustrating an arrangement of a low-noise amplifier 30 according to Embodiment 3.

FIG. 6 is a block diagram illustrating an arrangement of a low-noise amplifier 40 according to Embodiment 4.

FIG. 7 illustrates effects of setting of the time constant obtained by simulations.

FIG. 8 is a block diagram illustrating an arrangement of a low-noise amplifier 50 according to Embodiment 5.

FIG. 9 is a block diagram illustrating an arrangement of a low-noise amplifier 60 according to Embodiment 6.

FIG. 10 is a block diagram illustrating an arrangement of a low-noise amplifier 70 according to Embodiment 7.

FIG. 11 is a block diagram illustrating an arrangement of a low-noise amplifier 80 according to Embodiment 8.

FIG. 12 is a block diagram illustrating an arrangement of a low-noise amplifier 90 according to Embodiment 9.

FIG. 13 is a block diagram illustrating an arrangement of a low-noise amplifier 100 according to Embodiment 10.

### DESCRIPTION OF REFERENCE NUMERALS

10 Low-noise amplifier
11 Amplification circuit
20 Control circuit
21 Low-noise amplifier
21 Cascode amplifier
21a Grounded-gate transistor
21b Grounded-source transistor
21c Grounded-source transistor
22 Load element
23 Bias circuit
24 Input capacitor
30 Low-noise amplifier
31 Capacitance adding circuit
31a Capacitor
40 Low-noise amplifier
41 Resistance adding circuit
41a Resistor
50 Low-noise amplifier
51 Capacitance adding circuit
51a MOS transistor
51b Bias circuit
60 Low-noise amplifier
61 Capacitance adding circuit
70 Low-noise amplifier
71 Resistance adding circuit
71a MOS transistor
71b Bias circuit
80 Low-noise amplifier
81 Resistance adding circuit
90 Low-noise amplifier
100 Low-noise amplifier

### BEST MODE FOR CARRYING OUT THE INVENTION

Hereinafter, embodiments of the present invention are described with reference to the drawings. It should be noted that, in the following descriptions of the embodiments and variations, elements having functions similar to those of elements already described are denoted by the same reference numerals and the descriptions thereof are omitted.

### Embodiment 1 of the Invention

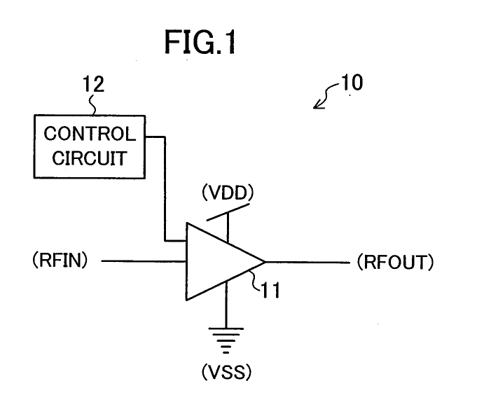

FIG. 1 is a block diagram illustrating an arrangement of a low-noise amplifier 10 according to Embodiment 1 of the present invention. The low-noise amplifier 10 amplifies a signal used for the IR-based UWB communication. Hereinafter, the signal inputted for amplification is referred to as the RF input signal.

The signal used in the IR type is an intermittent impulse signal in which periods with information (e.g. data of 0 and 1), hereinafter referred to as data periods, and data blank periods without information alternately occur. During the data periods, the information is identified depending on whether or not the impulse signal is present.

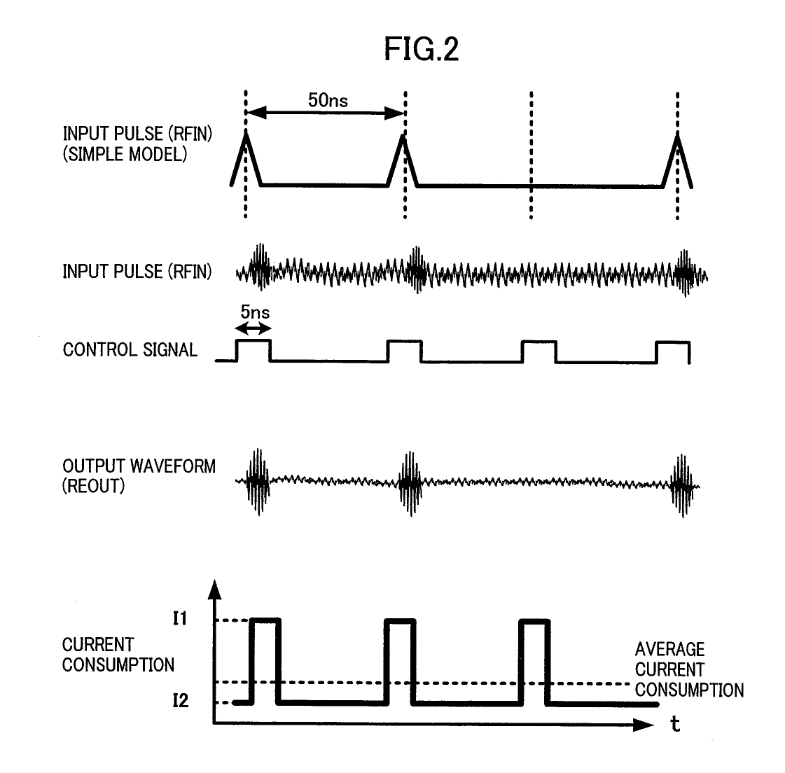

Also, each of the data periods and the data blank periods has a certain width. That is, the data periods emerge in predetermined cycles. In the present embodiment, as shown in FIG. 2, the data periods (in the signal waveform in the simplified model of FIG. 2, the periods during which the impulse signal is present) emerge in cycles of 50 ns. It means that, in this example, the signal is monitored in cycles of 50 ns to detect whether or not the impulse signal is present for obtaining information.

(Arrangement of the Low-Noise Amplifier 10)

The low-noise amplifier 10 has an amplification circuit 11 and a control circuit 12 as shown in FIG. 1.

The power supply (VDD) is supplied to the amplification circuit 11. The amplification circuit 11 outputs the signal (RFOUT) produced by amplifying the RF input signal (RFIN). Also, the amplification circuit 11 is arranged such that the ON/OFF state of the amplification operation is switched, i.e. power consumption is switched, in accordance with a control signal from the control circuit 12. Specifically, the amplification circuit 11 is in the ON state during periods where the control signal is H-level and is in the OFF state during periods where the control signal is L-level. Here, the system used for the amplification circuit 11 is not particularly limited. For example, the amplification circuit 11 may be a differential amplification circuit or a cascode amplifier described later.

The control circuit 12 operates in synchronization with the start timing of the data periods to output a pulse signal having a width larger than that of a data period as the control signal for the amplification circuit 11. In the present embodiment, the control circuit 12 outputs a pulse signal with a width of 5 ns as the control signal.

(Operation of the Low-Noise Amplifier 10)

When the RF input signal as shown in FIG. 2 is inputted to the low-noise amplifier 10, the control circuit 12 outputs the control signal to the amplification circuit 11 in cycles of 50 ns in synchronization with the start timing of the data periods. In accordance with the control signal outputted by the control circuit 12, the amplification circuit 11 is in the ON state during the data periods to perform the amplification operation and is in the OFF state during the data blank periods. As a result, the output of the low-noise amplifier 10 has a signal waveform where the impulse signal of the data periods is amplified as shown in FIG. 2 (see the output waveform (RFOUT) in FIG. 2).

Where the current consumption of the low-noise amplifier 10 is I1 during the ON periods of the amplification circuit 11 but 12 during the OFF periods of the amplification circuit 11, the current consumption of the low-noise amplifier 10 is switched between I1 and 12 depending on the ON/OFF state of the amplification operation of the amplification circuit 11, and the average current consumption is smaller than IL

Thus, according to the present embodiment, reduction in the average current consumption is possible since the power consumption can be controlled during the periods where the RF input signal is inputted.

### Embodiment 2 of the Invention

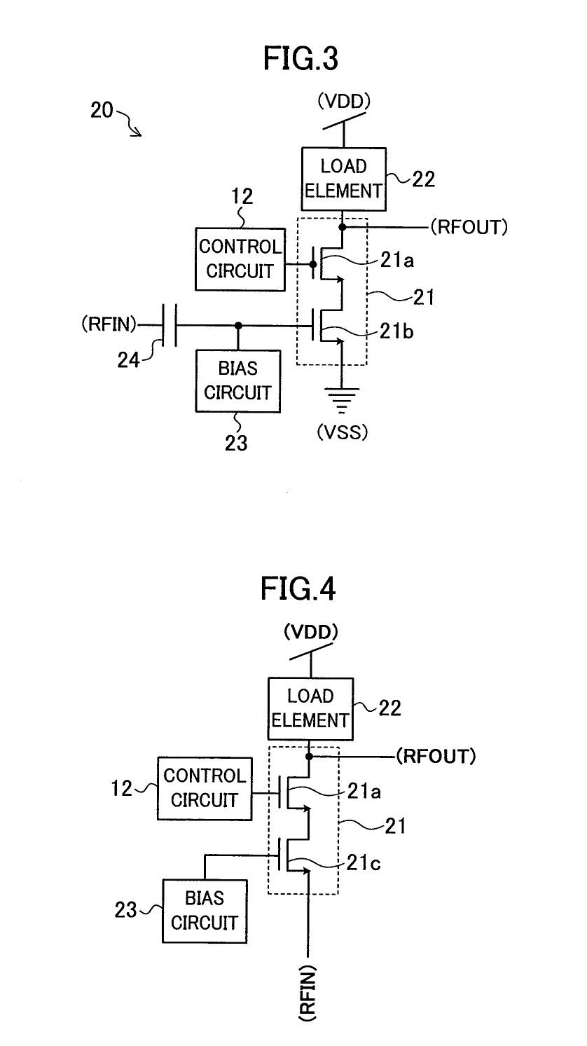

FIG. 3 is a block diagram illustrating an arrangement of a low-noise amplifier 20 according to Embodiment 2 of the present invention. The low-noise amplifier 20 shows a specific arrangement example of the amplification circuit 11 of Embodiment 1.

The low-noise amplifier 20 has a control circuit 12, a cascode amplifier 21, a load element 22, a bias circuit 23, and an input capacitor 24 as shown in FIG. 3.

The cascode amplifier 21 converts the inputted RF input signal (RFIN) to a current signal and outputs the resultant signal. Specifically, the cascode amplifier 21 has a grounded-gate transistor 21a and a grounded-source transistor 21b.

In the grounded-gate transistor 21a, the source is connected to the drain of the grounded-source transistor 21b and the drain is connected to the power supply (VDD) via the load element 22.

In the grounded-source transistor 21b, the source is grounded and the RF input signal is inputted to the gate via the input capacitor 24.

The load element 22 converts the current signal outputted by the cascode amplifier 21 to the voltage signal (RFOUT).

The bias circuit 23 supplies a bias potential to the gate of the grounded-source transistor 21b so that the grounded-source transistor 21b can perform the amplification operation.

The input capacitor 24 eliminates a direct current component from the RF input signal.

(Operation of the Low-Noise Amplifier 20)

Also in the low-noise amplifier 20, the control circuit 12 outputs a control signal to the cascode amplifier 21 in cycles of 50 ns in synchronization with the start timing of the data periods. In accordance with the control signal, the grounded-gate transistor 21a is in the ON state during the data periods and is in the OFF state during the data blank periods. That is, the cascode amplifier 21 is in the ON state during the data periods to perform the amplification operation and is in the OFF state during the data blank periods.

Accordingly, also in the low-noise amplifier 20, reduction in the average current consumption is possible since the power consumption can be controlled during the periods where the RF input signal to be amplified is inputted.

In addition, in the present embodiment, high-speed ON/OFF control of the amplification operation is possible. For example, if it were attempted to control the gate potential of a transistor to which a high frequency signal (RF input signal) is inputted, like the grounded-source transistor 21b, for the purpose of controlling the ON/OFF state of the transistor, a switching element (e.g. a MOS transistor) would need to be connected to the gate via a load element having a large resistance value. This is because the high frequency signal needs to be prevented from leaking to the switching element. Thus, if the load element having a large resistance value were connected to the grounded-source transistor 21b, high-speed switching by the switching element would be difficult. Therefore, it is difficult to apply the system where the ON/OFF state of the transistor to which a high frequency signal is inputted is controlled to a low-noise amplifier amplifying a high frequency signal.

In contrast to this, in the present embodiment, the ON/OFF state of the amplification operation is controlled by a transistor (grounded-gate transistor 21a) different from the transistor to which a high frequency signal is inputted (grounded-source transistor 21b). That is, a load element having a large resistance value needs not to be connected to the gate since the high frequency signal is not inputted to the grounded-gate transistor 21a, and high-speed switching is thus possible.

Thus, in this embodiment, it is possible to switch the ON/OFF state of the amplification operation at a high speed by using different transistors for the transistor to which a high frequency signal is inputted and the transistor controlling the ON/OFF state of the amplification operation. Therefore, the present embodiment is effective when applied to a low-noise amplifier for IR communications, especially during an intermittent operation at a high speed of, for example, 10 nsec.

Furthermore, in the present embodiment, it is also possible to prevent deterioration of the frequency characteristics that would be caused by variations in the input impedance. If, for example, the ON/OFF state of the grounded-source transistor 21b to which the RF input signal is inputted were controlled by the control circuit 12, the impedance of the control circuit 12 would be applied to the grounded-source transistor 21b, and therefore variations in the input impedance of the low-noise amplifier due to variations in temperature and voltage could be caused and the frequency characteristics could deteriorate.

In contrast to this, in the present embodiment, the input impedance of the cascode amplifier 21 is determined in accordance with a parasitic capacitance and a transconductor value of the grounded-source transistor 21b and thus is not affected by the ON/OFF control of the control circuit 12. That is, increase in the time that it takes for the signal to rise and deterioration of the frequency characteristics caused by increased parasitic constituents can be diminished by using different transistors for the transistor to which the high frequency signal is inputted and the transistor controlling the ON/OFF state of the amplification operation.

### Variation of Embodiment 2 of the Present Invention

FIG. 4 is a block diagram illustrating an arrangement of a low-noise amplifier according to a variation of Embodiment 2. This variation also includes the control circuit 12, the cascode amplifier 22, and the bias circuit 23. In this case, however, the RF input signal is inputted to the source of a grounded-source transistor 21c provided instead of the grounded-source transistor 21b. Thus, performing the amplification operation is possible even when the RF input signal (RFIN) is inputted to the source.

### Embodiment 3 of the Invention

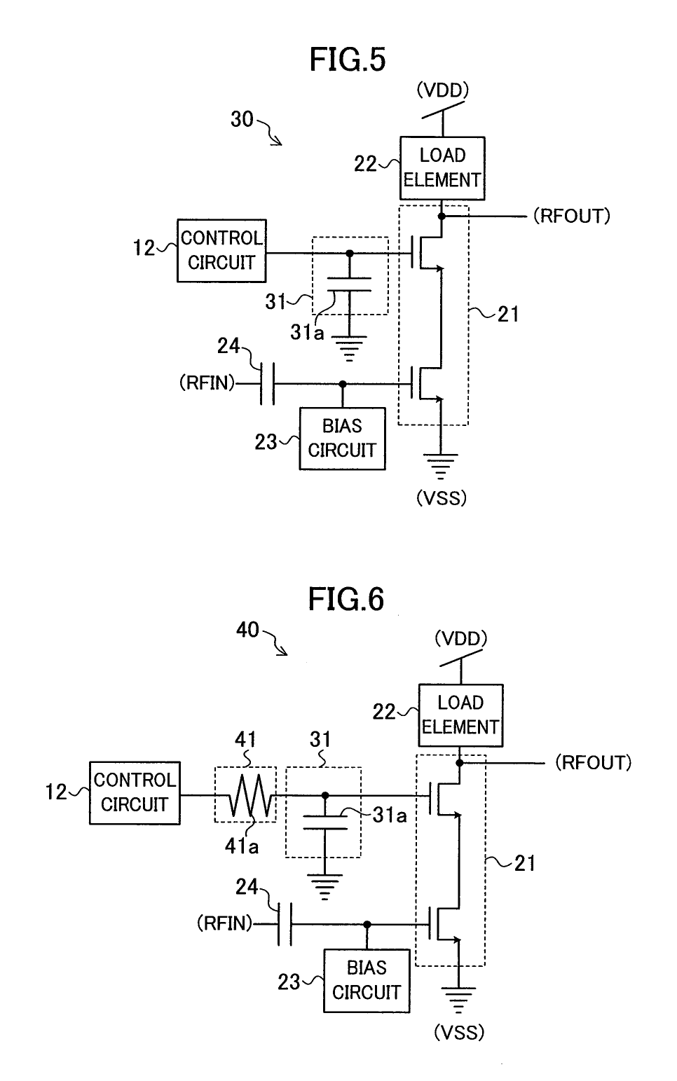

FIG. 5 is a block diagram illustrating an arrangement of a low-noise amplifier 30 according to Embodiment 3 of the present invention. The low-noise amplifier 30 includes a capacitance adding circuit 31 in addition to the components of the low-noise amplifier 20 as shown in FIG. 5.

The capacitance adding circuit 31 has a capacitor 31a. A terminal of the capacitor 31a is connected to the gate of the grounded-gate transistor 21a and the other terminal of the capacitor 31a is grounded.

In the present embodiment, improving the frequency characteristics of the cascode amplifier 21 is possible since the capacitor 31a is provided as described above.

### Embodiment 4 of the Invention

FIG. 6 is a block diagram illustrating an arrangement of a low-noise amplifier 40 according to Embodiment 4 of the present invention. The low-noise amplifier 40 includes a resistance adding circuit 41 in addition to the components of the low-noise amplifier 30 as shown in FIG. 6.

The resistance adding circuit 41 is interposed between the gate of the grounded-gate transistor 21a and the control circuit 12. Specifically, the resistance adding circuit 41 has a resistor 41a. A terminal of the resistor 41a is connected to the gate of the grounded-gate transistor 21a and the other terminal of the resistor 41a is connected to the output of the control circuit 12.

In the present embodiment, it is possible to set the time constant between the control circuit 12 and the cascode amplifier 21 by means of the capacitor 31a and the resistor 41a that are provided between the cascode amplifier 21 and the control circuit 12.

Specifically, the capacitance value (C) of the capacitor 31a and the resistance value (R) of the resistor 41a are set so as to satisfy the following relationship.

Vo=Vi×[1−exp{−t/(CR)}] Formula

where Vo represents the gate potential of the grounded-gate transistor, Vi represents the output potential of the control circuit, and t represents the time periods extending from the time at which the control circuit outputs a signal for controlling the gate potential of the grounded-gate transistor to the time at which Vo exceeds the sum potential of the threshold voltage and the saturation drain voltage of the grounded-gate transistor. The values of C and R are set specifically by determining the product of the resistance value and the capacitance and considering the layouts on a semiconductor substrate and the like. Now, R in the formula includes a resistance added and the output resistance of the control circuit.

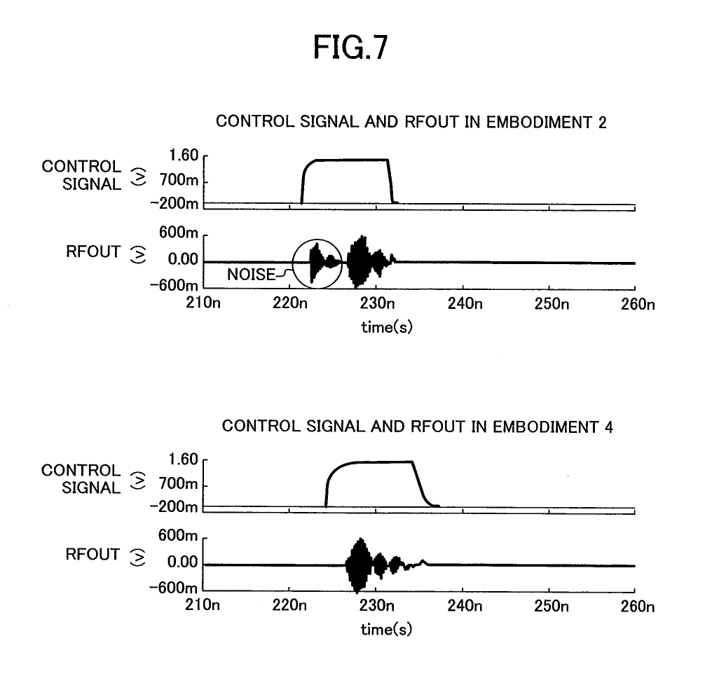

FIG. 7 illustrates the effects of setting of the time constant obtained by simulations. For example, in the low-noise amplifier 20 according to Embodiment 2, noise occurred in the output signal (RFOUT) after the rising of the control signal. However, in the low-noise amplifier 40 according to Embodiment 4, noise hardly occurred.

In the simulation, the resistance value of the resistor 41a was 200 S2 and the capacitance value of the capacitor 31a was 9 pF. Also, the resistance value of the resistor 41a was simulated in the range of ±20% from the above-described value and the capacitance value of the capacitor 31a was simulated in the range of ±10% from the above-described value, and similar results were obtained.

As described above, according to the present embodiment, it is possible to reduce switching noise that occurs when the ON/OFF (operational/non-operational) state of the cascode amplifier 21 is switched.

### Embodiment 5 of the Invention

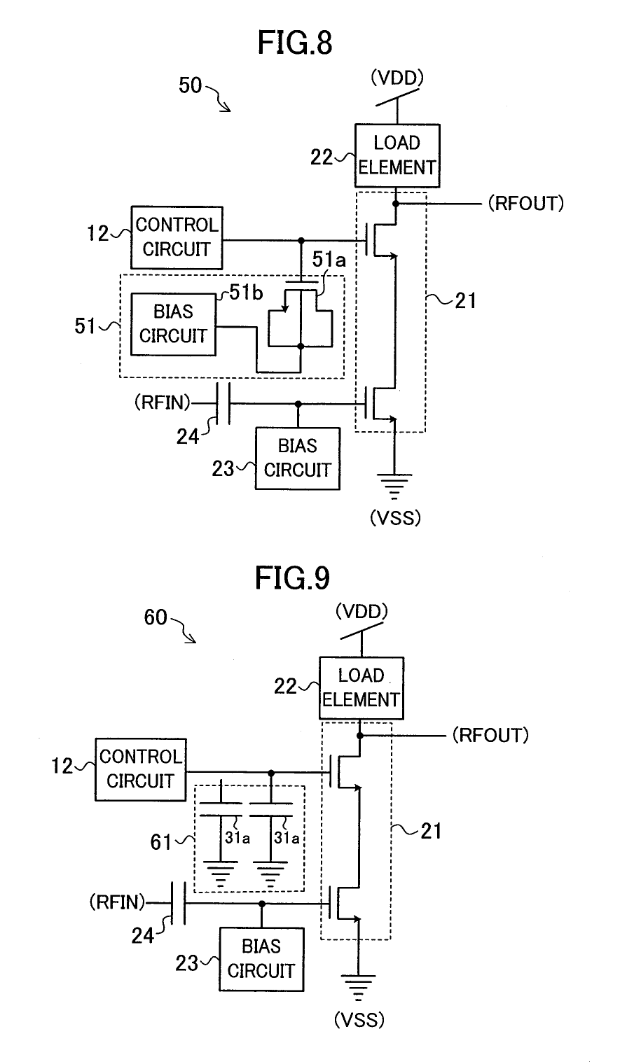

FIG. 8 is a block diagram illustrating an arrangement of a low-noise amplifier 50 according to Embodiment 5 of the present invention. The low-noise amplifier 50 includes a capacitance adding circuit 51 instead of the capacitance adding circuit 31 of the low-noise amplifier 30 as shown in FIG. 8.

Specifically, the capacitance adding circuit 51 has a MOS transistor 51a and a bias circuit 51b.

The gate of the MOS transistor 51a is connected to the gate of the grounded-gate transistor 21a. The source, drain, and back gate of the MOS transistor 51a are connected to one another.

The bias circuit 51b controls the potential of the source, drain, and back gate of the MOS transistor 51a under the control of a device outside the low-noise amplifier 50.

The capacitance adding circuit 51 serves as a capacitor with which a capacitance can be changed due to the above-described arrangement. Therefore, according to the present embodiment, the capacitance added to the grounded-gate transistor 21a can be adjusted, and thereby the high frequency characteristics of the cascode amplifier 21 can be optimized.

In this embodiment, a diode may be used instead of the MOS transistor 51a.

### Embodiment 6 of the Invention

FIG. 9 is a block diagram illustrating an arrangement of a low-noise amplifier 60 according to Embodiment 6 of the present invention. The low-noise amplifier 60 includes a capacitance adding circuit 61 instead of the capacitance adding circuit 31 of the low-noise amplifier 30 as shown in FIG. 9.

Specifically, the capacitance adding circuit 61 has a plurality of capacitors 31a (2 capacitors in the example of FIG. 9). Each of the capacitors 31a has such a structure that whether or not the gate of the grounded-gate transistor 21a is grounded is switchable under the control of a device outside the low-noise amplifier 60.

Accordingly, also in the present embodiment, the capacitance added to the grounded-gate transistor 21a can be adjusted, and thereby the high frequency characteristics of the cascode amplifier 21 can be optimized.

Moreover, compared with the case of the low-noise amplifier 50, the present embodiment enables the capacitance to be adjusted in a wider range when the capacitance of the capacitor 31a is properly set. Therefore, the present embodiment is useful when the high frequency characteristics of the cascode amplifier 21 need to be changed in a wide range such as when the temperatures used vary in a large range.

### Embodiment 7 of the Invention

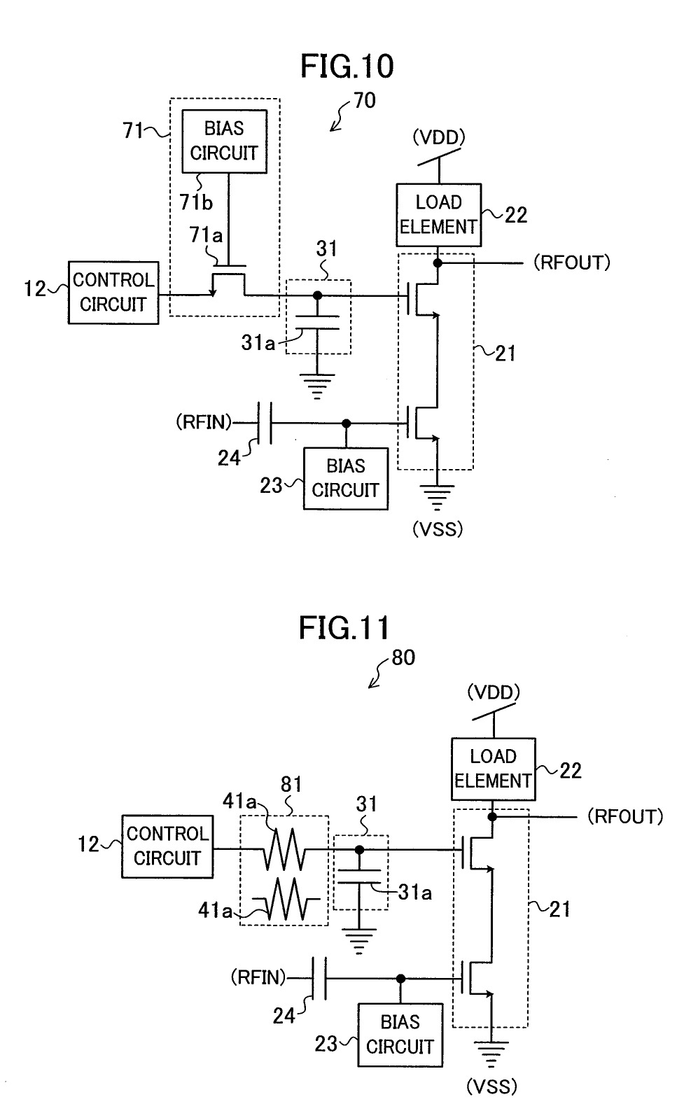

FIG. 10 is a block diagram illustrating an arrangement of a low-noise amplifier 70 according to Embodiment 7 of the present invention. The low-noise amplifier 70 includes a resistance adding circuit 71 instead of the resistance adding circuit 41 of the low-noise amplifier 40 as shown in FIG. 10.

Specifically, the resistance adding circuit 71 has a MOS transistor 71a and a bias circuit 71b.

The source of the MOS transistor 71a is connected to the output of the control circuit 12 and the drain of the MOS transistor 71a is connected to the gate of the grounded-gate transistor 21a.

The bias circuit 71b controls the potential of the gate of the MOS transistor 71a under the control of a device outside the low-noise amplifier 70.

Accordingly, the MOS transistor 71a serves as a load element whose resistance value varies depending on the potential applied by the bias circuit 71b. Thus, according to this embodiment, it is possible to adjust the time constant between the control circuit 12 and the cascode amplifier 21. Therefore, it is possible to more effectively reduce switching noise that occurs when the operational/non-operational state of the cascode amplifier 21 is switched.

### Embodiment 8 of the Invention

FIG. 11 is a block diagram illustrating an arrangement of a low-noise amplifier 80 according to Embodiment 8 of the present invention. The low-noise amplifier 80 includes a resistance adding circuit 81 instead of the resistance adding circuit 41 of the low-noise amplifier 40 as shown in FIG. 11.

The resistance adding circuit 81 has a plurality of resistors 41a (2 resistors in the example of FIG. 11). Each of the resistors 41a has such a structure that whether or not the control circuit 12 and the gate of the grounded-gate transistor 21a are connected together is switchable under the control of a device outside the low-noise amplifier 80.

Accordingly, also in the present embodiment, it is possible to adjust the time constant between the control circuit 12 and the cascode amplifier 21.

Moreover, compared with the case of the low-noise amplifier 70, the present embodiment enables the resistance value to be adjusted in a wider range when the resistance value of the resistor 41a is properly set. Therefore, the present embodiment is useful when the time constant needs to be changed in a wide range such as when the temperatures used vary in a large range.

### Embodiment 9 of the Invention

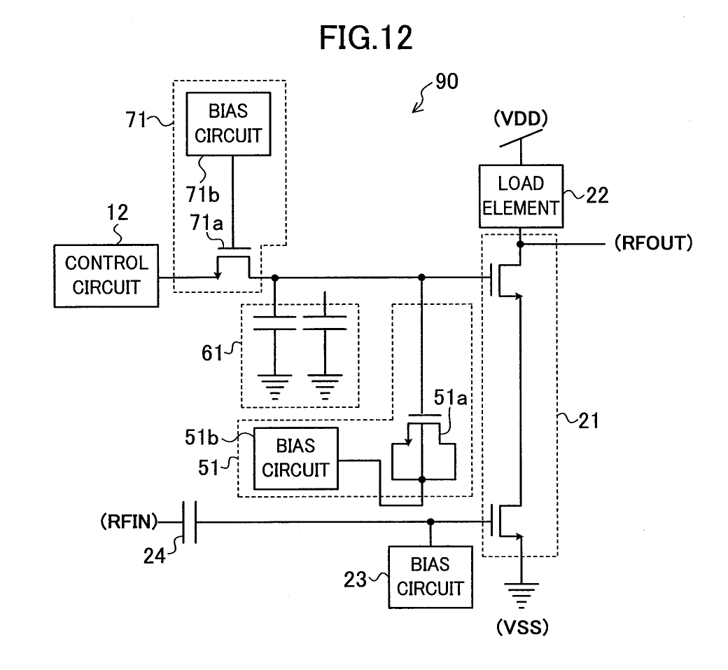

FIG. 12 is a block diagram illustrating an arrangement of a low-noise amplifier 90 according to Embodiment 9 of the present invention. The low-noise amplifier 90 includes a capacitance adding circuit 51 and a capacitance adding circuit 61 instead of the capacitance adding circuit 31 of the low-noise amplifier 70 as shown in FIG. 12. Thus, in the present embodiment, for example, when the capacitance adding circuit 61 selects the value of the capacitor 31a for changing the capacitance in a wide range, the capacitance is adjusted in a wide range in the capacitance adding circuit 61 and the capacitance is finely adjusted in the capacitance adding circuit 51. Thus, according to the present embodiment, it is possible to adjust the time constant in a wide range and with high accuracy.

### Embodiment 10 of the Invention

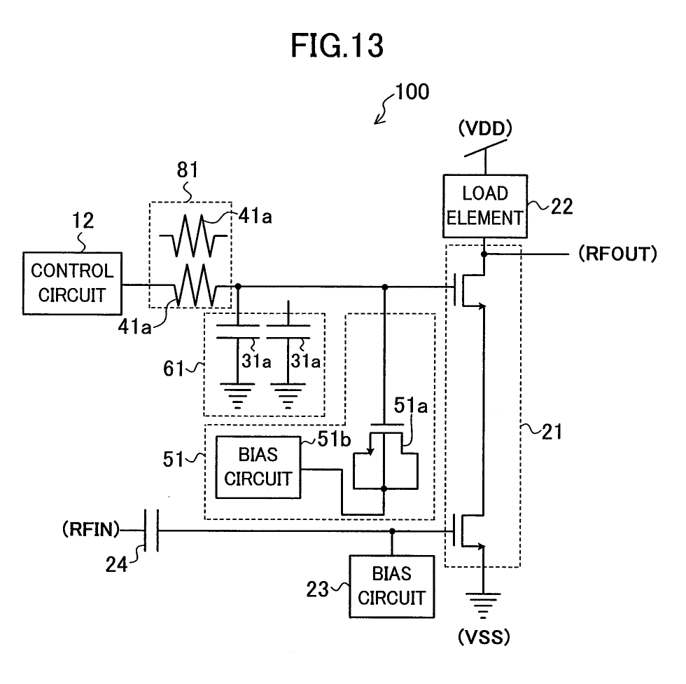

FIG. 13 is a block diagram illustrating an arrangement of a low-noise amplifier 100 according to Embodiment 10 of the present invention. The low-noise amplifier 100 includes a resistance adding circuit 81 instead of the resistance adding circuit 71 of the low-noise amplifier 90 as shown in FIG. 13. Thus, also in the present embodiment, it is possible to more properly adjust the time constant between the control circuit 12 and the cascode amplifier 21.

In each of the low-noise amplifiers according to Embodiment 3 through Embodiment 10, the RF input signal (RFIN) is inputted to the gate of the grounded-source transistor 21b. Also in the low-noise amplifiers of these embodiments, the RF input signal may be inputted to the source of the grounded-source transistor 21c as shown in the variation of Embodiment 2.

Also, the elements described in the embodiments may be variously combined so long as such combinations are logically possible. For example, the resistance adding circuit 81 may be combined with the low-noise amplifier 70 of Embodiment 7, in which it is possible to adjust the resistance value in a wide range and with high accuracy. That is, it is possible to adjust the time constant in a wide range and with high accuracy.

The amplification circuit 11 (or the cascode amplifier 21) is not necessarily required to be in the OFF state during every data blank period. It means that reducing the average power consumption is possible even when the amplification circuit 11 (or the cascode amplifier 21) is controlled to be in the OFF state during part of the data blank periods.

The cascode amplifier 21 may include 3 or more cascode-connected transistors. In this case, when the transistor to which the high frequency signal is inputted and the transistor controlling the ON/OFF state of the amplifying operation are different, high-speed control of the ON/OFF state of the amplifying operation and prevention of deterioration of the frequency characteristics caused by variations in the input impedance are possible.

The impulse signal in IR communications is an example of the signals applicable to the above-described embodiments, to which the present invention is not limited. Any input signal in which data periods with information and data blank periods without information alternately occur is applicable.

### INDUSTRIAL APPLICABILITY

A low-noise amplifier according to the present invention has the effect that, in the process of amplifying an input signal in which data periods with information and data blank periods without information alternately occur, such as an impulse signal in IR communications, reduction in power consumption is possible since the power consumption can be controlled even during periods where the signal is inputted, and is useful as a low-noise amplifier for amplifying the input signal, a radio communication system using the low-noise amplifier, and the like.

1. A low-noise amplifier for amplifying an input signal in which data periods and data blank periods alternately occur, the input signal including information during the data periods but no information during the data blank periods, the low-noise amplifier comprising:
an amplification circuit for amplifying the input signal, power consumption of the amplification circuit being switchable; and
a control circuit switching the power consumption of the amplification circuit such that the data blank periods include an interval during which the power consumption of the amplification circuit is smaller than during the data periods.

2. The low-noise amplifier of claim 1, wherein:
the amplification circuit is a cascode amplifier converting the input signal to a current signal, the cascode amplifier including a cascode-connected, grounded-gate transistor and a transistor to which the input signal is inputted; and
the control circuit controls a gate potential of the grounded-gate transistor to switch the power consumption of the amplification circuit.

3. The low-noise amplifier of claim 2, further comprising a capacitance adding circuit for adding a capacitance for grounding a gate of the grounded-gate transistor.

4. The low-noise amplifier of claim 3, further comprising a resistance adding circuit interposed between the gate of the grounded-gate transistor and the control circuit for adding a resistance for setting the time constant between the control circuit and the amplification circuit.

5. The low-noise amplifier of claim 3, wherein the capacitance adding circuit is a capacitive element having a variable capacitance.

6. The low-noise amplifier of claim 3, wherein the capacitance adding circuit includes a plurality of capacitors with which whether or not the gate of the grounded-gate transistor is grounded is switchable.

7. The low-noise amplifier of claim 4, wherein the resistance adding circuit is a load element having a variable resistance value.

8. The low-noise amplifier of claim 4, wherein the resistance adding circuit includes a plurality of load elements with which whether or not the control circuit and the gate of the grounded-gate transistor are connected together is switchable.

9. The low-noise amplifier of claim 2, further comprising:
a first capacitance adding circuit and second capacitance adding circuit for adding the capacitance for grounding the gate of the grounded-gate transistor; and
a resistance adding circuit interposed between the gate of the grounded-gate transistor and the control circuit for adding a resistance for setting the time constant between the control circuit and the amplification circuit,
wherein the first capacitance adding circuit is a capacitive element having a variable capacitance, and
the second capacitance adding circuit includes a plurality of capacitors with which whether or not the gate of the grounded-gate transistor is grounded is switchable.

10. The low-noise amplifier of claim 3, further comprising a first resistance adding circuit and second resistance adding circuit interposed between the gate of the grounded-gate transistor and the control circuit for adding a resistance for setting the time constant between the control circuit and the amplification circuit,
wherein the first resistance adding circuit is a load element having a variable resistance value, and
the second resistance adding circuit includes a plurality of load elements with which whether or not the control circuit and the gate of the grounded-gate transistor are connected together is switchable.

11. The low-noise amplifier of claim 4, wherein the resistance value (R) of the resistance added by the resistance adding circuit and the capacitance value (C) of the capacitance added by the capacitance adding circuit satisfy the relationship of
Vo=Vi×[1−exp{−t/(CR)}]
where Vo represents the gate potential of the grounded-gate transistor, Vi represents an output potential of the control circuit, t represents a time period extending from a time at which the control circuit outputs a signal for controlling the gate potential of the grounded-gate transistor to a time at which Vo exceeds a sum potential of a threshold voltage and a saturation drain voltage of the grounded-gate transistor, and R in the formula includes a resistance added and an output resistance of the control circuit.

12. A radio communication system of an impulse radio type for communications performed based on an impulse signal, comprising the low-noise amplifier of claim 1.
